(19) United States
(12) Patent Application Publication
(10) Pub. No.: US 2024/0234396 A1
(43) Pub. Date: Jul. 11, 2024

(54) COLOR-TUNABLE LED ELEMENTS AND DISPLAY SYSTEMS AND METHODS THEREOF

(71) Applicant: INNOVATION SEMICONDUCTOR, Rochester, NY (US)

(72) Inventor: Matthew T. HARTENSVELD, Wyckoff, NJ (US)

(73) Assignee: INNOVATION SEMICONDUCTOR, Rochester, NY (US)

(21) Appl. No.: 18/409,112

(22) Filed: Jan. 10, 2024

Related U.S. Application Data
(60) Provisional application No. 63/438,435, filed on Jan. 11, 2023.

(51) Int. Cl. H01L 25/16; H01L 33/00; H01L 33/06

(52) U.S. Cl. CPC H01L 25/167; H01L 33/0075; H01L 33/06

(57) ABSTRACT

A color-tunable LED system that is configured to emit a variety of peak wavelengths of light in response to variations in a driving current density includes an n-type region, a p-type region, and a multiple quantum well (MQW) region formed between the n-type region and the p-type region. The MQW region includes parallel layers, each alloyed with a percentage of Indium to enable a range of light emission between 400 and 600 nm, and one or more shaped depressions formed within a portion of the parallel layers. Each of the one or more shaped depressions has a lower concentration of the alloyed percentage of the Indium than other portions of the parallel layers. Transition regions between the one or more shaped depressions and the other portions of the parallel layers have a higher concentration of the alloyed percentage of the Indium which decreases with distance from the one or more shaped depressions. Use of the monolithic color-tunable LED system can make use of a single LED to act as a pixel.

This application claims the benefit of U.S. Provisional Patent Application No. 63/438,435 filed Jan. 11, 2023, the entirety of which is incorporated herein by reference.

### FIELD

This technology relates to color-tunable light emitting diodes, LED systems and LED display systems including such light emitting diodes and methods thereof.

### BACKGROUND

Displays based on inorganic light emitting diodes (LEDs), particularly smaller mini-LEDs and μ-LEDs, are viewed by the display industry as an emerging successor to those including organic light emitting diodes (OLEDs) for many applications including both near eye displays and larger form factor displays viewed at a distance. They offer many advantages, including high efficiency, environmental ruggedness, greater scaling, and higher brightness.

However, the development of improved inorganic LEDs and LED displays has been hampered by issues relating to integration of separately fabricated red, green, and blue LEDs into a functional and controllable LED system capable of emitting light across the visible spectrum. Each LED includes layers of an electron rich n-type region, a hole rich p-type region, and a multiple quantum well (MQW) region between the n-type and p-type regions. The MQW region is composed of multiple individual quantum wells, which possess a smaller energy bandgap due to alloying, which are positioned between higher energy bandgap materials. The smaller energy bandgap quantum wells confine electrons and holes to facilitate recombination and corresponding light emission.

By way of example, blue and green LEDs are commonly based on the III-N material system. Indium is alloyed with GaN in different amounts to shrink the bandgap of the quantum wells. Where blue light can be produced with quantum wells containing ˜10% Indium, additional Indium incorporation leads to longer wavelength emissions such as green. Use of only the III-N material system for blue, green, and red is limited due to the difficulties in incorporating the high levels of Indium needed for red. As the Indium concentration increases, issues of strain and solubility arise. Conventionally, red emitters instead make use of the III-V material system with AlInGaP. Relying on these disunified material systems, associated respectively with blue and green and separately red, typically necessitates the separate manufacturing of each, followed by integration with Silicon-based control electronics in a display. This integration typically leads to higher costs and more complex manufacturing methods.

To avoid the need for separate LED growths, there have been three main approaches to develop higher efficiency red emitting and overall visible light emitting color tunable InGaN LEDs that reduce the integration issues noted above, namely Europium doping, use of a porous GaN substrate, or nanowire growth. Each of these approaches, however, suffers from issues of complex manufacturing of a display and compromised emission uniformity.

### SUMMARY

Examples of this technology relate to color-tunable LEDs, LED systems and display systems, which can be monolithic in nature by using a common, single crystalline material system, configured to emit a variety of peak wavelengths of light in response to variations in a driving current density. Both LEDs and LED systems are desirably fabricated in a single crystal GaN material system, also referred to as a monolithic system in examples herein, based on common processing of the GaN. Single crystal is defined herein as an ordered arrangement of atoms forming a single wurtzite crystal. The LEDs and LED systems include an n-type region, a p-type region with an optional electron blocking layer (EBL), and a multiple quantum well (MQW) region formed between the n-type region and the p-type region. The MQW region includes parallel layers, each alloyed with a percentage of Indium to enable a range of light emission between 400 and 600 nm. The MQW region is formed over a first active doped layer or region that is selectively patterned along one surface with depressions of one or more shapes and with one or more spacing configurations to promote controlled color emissions in MQW layers of a MQW region. Each of the one or more portions of the MQW layers of a MQW region that conform to the depressions in the first active doped layer has a lower concentration of the alloyed percentage of the Indium than other portions of the MQW layers of the MQW region. Transition regions between areas conforming to depressions in the first active doped layer and other portions of the MQW layers have a higher concentration of the alloyed percentage of the Indium than areas conforming to depressions in the first active layer, which decreases with distance from the one or more such depressions.

A method for making a color-tunable LED system, configured to emit a variety of peak wavelengths of light in response to variations in the driving current density, includes forming a first active doped n-type or p-type layer. In various examples, this first active doped n-type or p-type layer may be etched or otherwise patterned to create a variety of depressions of various shapes, sizes, sidewall angles or other characteristics and spacing configurations as referred to elsewhere herein. A MQW region is grown on the first active doped n-type or p-type layer. The MQW region includes parallel layers, each alloyed with a percentage of Indium to enable a range of light emission between 400 and 600 nm, with the layers of the MQW region conforming to one or more of the shaped depressions formed within the first active doped layer. Portions of the parallel layers conforming to depressions patterned in the first active doped layer have a lower concentration of the alloyed percentage of the Indium than the other portions of the parallel layers. Transition regions between the portion of the parallel layers conforming to the depressions in the first active layer and other portions of the parallel layers have a higher concentration of the alloyed percentage of the Indium, which decreases with distance from the portions of the parallel layers conforming to the depressions. A second active doped layer that is of opposite charge to the first active layer is grown on the MQW region.

With examples of this technology, each color-tunable LED can function as one pixel element, with each such LED capable of rapidly switching, in response to correspondingly rapid changes in driving current density, between two or more wavelengths of emission such that a single color is perceived by the eye. Individual pixels elements can be arrayed many times to create a full display system for any desired shape or resolution. A plurality of color-tunable LEDs can be combined and arrayed to form a complete, optionally monolithic LED display system. With other examples of this technology, a functioning pixel element can optionally comprise more than one monolithic color-tunable LED, each with the same or different density or design of depressions patterned in the first active doped layer and capable of emitting visible light as a variety of colors or a fixed color.

In other examples of this technology, the color-tunable LED may have additional components added to create the basis of a pixel element. The additional components can take the form of device elements, such as transistors, capacitors, and diodes by way of example. The device elements, together with the color-tunable LEDs, may be electrically connected to form a variety of circuits, by way of example, current sources and active-matrix circuits for each pixel element. The pixel elements may function by having each color-tunable LED rapidly switch, in response to correspondingly rapid changes in driving current density, between two or more wavelengths of emission such that a single color is perceived by the eye. Individual pixel elements can be arrayed many times to create a full color-tunable LED display system of any desired shape or resolution.

In examples where the color-tunable LED is included in a pixel element, additional circuitry may be integrated to feed in voltage and current signals to drive the LED arrays and together comprise an LED display system. The circuitry may take the form of external chips or be integrated on-chip with the LED to create an optionally monolithic LED display system.

Color tunable LEDs and color-tunable LED display systems as described and claimed herein provide a number of advantages and can be effectively utilized in a number of different applications, such as micro displays and larger format displays, commercial lighting, light-based data communications, and more. In particular, examples of this technology provide color-tunable LEDs that can emit light across the visible spectrum without requiring any added color converters. This reduces complexity, offers better performance, and lowers cost for many applications. Monolithic is defined for some examples herein as a common InGaN/GaN, III-N, material system used exclusively within the same wafer. Variations in examples of this technology are further able to provide monolithic color-tunable LEDs without Eu doping, use of a porous GaN substrate, or nanowire growth. Further, in other examples, single LEDs can be configured to function as a pixel, rather than the use of three LEDs to emit, selectively, red, green, and blue light, the common RGB approach used broadly today. Reducing the number of LED subpixels required to form pixels increases potential display resolution and reduces the footprint. This smaller footprint is a particular advantage in μ-LED displays intended for near eye applications such as virtual or augmented reality. It also lowers cost and enables more efficient manufacturing.

Further, the problems discussed in the background can be addressed by using an alternative method to realize a simpler system, in some examples using a monolithic, i.e. universal and common single crystalline material system, such as single crystal GaN, in fabricating LED elements/systems. Monolithic is defined herein as a common InGaN/GaN, III-N, material system used exclusively for all semiconductor growth on the same wafer. III-N is defined herein as the class of materials including GaN and elements alloyed with GaN, such as Indium or Aluminum.

### BRIEF DESCRIPTION OF THE DRAWINGS

FIG. 1A is a cross-sectional image of an example of patterned depressions formed along one surface of a first active doped layer (n-type material in the example) prior to forming the final layers;

FIG. 1B is a bird's eye image of a section of FIG. 1A showing the different shaped depressions patterned along one surface of the first active doped layer (n-type in the example) with the edges shown and a dashed lined to symbolize the cross section for FIG. 1A;

FIG. 1C is a cross-section image of an example of a color-tunable LED system incorporating a first active doped layer (n-type material in the example) patterned along one surface with depressions of multiple shapes and spacings that promote controlled color emissions in the MQW layers of the MQW region of the LED;

FIG. 2 is a graph of an example illustrating how a single color-tunable LED can be driven with different current densities to produce different colors of equal intensities by varying the duty cycle and current;

FIG. 3 is a graph of an example showcasing operation of a single color-tunable LED being driven to produce a purple color as perceived by the eye by rapidly alternating between pulsed current densities that produce emission of red and blue wavelengths;

FIG. 4 is a graph of an example showcasing operation of a single color-tunable LED being driven to produce white light as perceived by the eye by rapidly alternating between pulsed current densities that produce emission of yellow and blue wavelengths.

### DETAILED DESCRIPTION

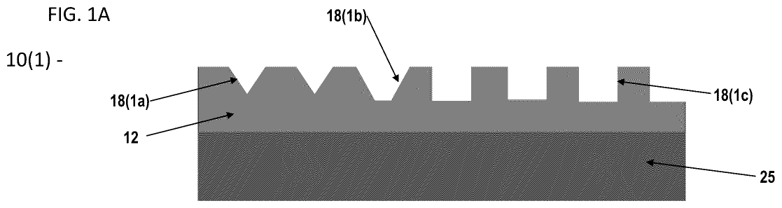

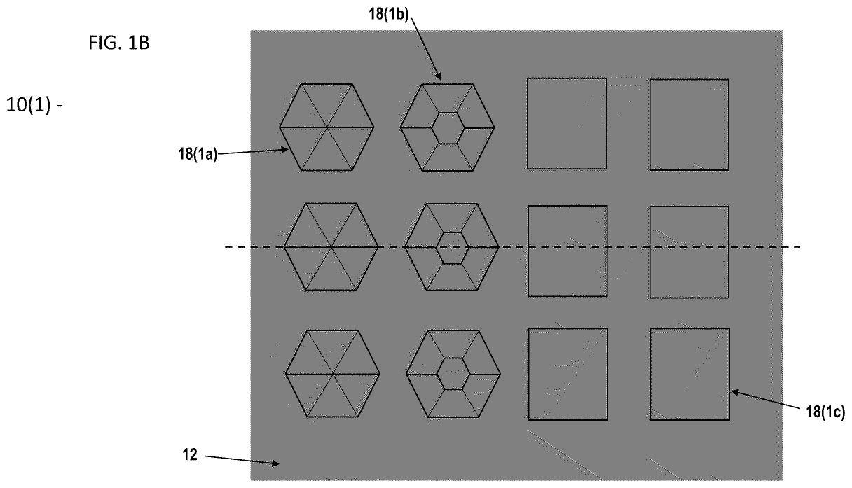

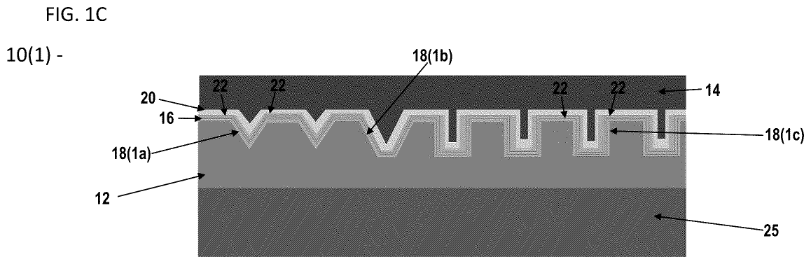

Examples of the color-tunable LED technology, as illustrated in FIGS. 1A, 1B and 1C, provides several advantages including providing a color-tunable LED system which can be effectively utilized in several different applications, such as displays, commercial lighting, communications, and more, and can optionally be made with a single material system.

Referring more specifically to FIG. 1A, in this example to create a color-tunable LED system 10(1) a patterned first doped active layer comprising an n-GaN layer is formed on an initial growth substrate 25, such as silicon or sapphire by way of example, although other types and/or numbers of doped layers and/or substrates may be used. The surface of the first active layer 12 is in this example patterned with shaped depressions 18(1a-c), such as outer periphery or cross-sectional shapes comprising circles, triangles, squares, pentagons, hexagons, or arrangements made of multiple such shapes, with top surface diameters from about 150 nm to about 10 μm, spacings between the depressions 18(1a-c) of about 150 nm to about 10 μm, and height or depth differences from the surface of the depressions 18(1a-c) less than about 5 μm to enable the color-tunable emission in the MQW region, although other patterns, with other sizes, spacing, and/or shapes may be used. In some examples, the side walls of one or more of the depressions 18(1a-c) can be at angle with reference to the substrate between 0 to 90 degrees in some examples and other ones of the depressions 18(1a-c) can be between 90 to 180 degrees, although in other examples other types and/or combinations of angles for the side walls of the depressions 18(1a-c) with reference to the substrate can be used. By way of a further example, the sidewalls of the depressions 18(1a-c) can have positive, negative, and/or perpendicular sloped sidewalls with respect to the growth substrate 25. The depressions 18(1a-c) are added for the purposes of tailoring the Indium content to control the emission spectrum from LEDs due to the differences in Indium incorporation along different crystal planes. These depressions 18(1a-c) locally relax the crystal structure, modifying the Indium absorption in the MQW region.

In this example, use of a shaped depression 18(1c) which has a 90-degree angle relative to the substrate is expected to enhance short wavelength, blue, emission from the color-tunable LED system 10(1). Additionally, in this example use of a positive sloped shaped depression 18(1a-b) or negative sloped shaped depression less than or greater than 90 degrees in reference to the substrate, respectively, can promote longer wavelength, red, emission from the color-tunable LED system 10(1). Accordingly, in these examples selective incorporations of different shaped depressions 18(1a-c) can be used to tailor the color emission from the color-tunable LED system 10(1) at a fixed current density.

The geometry and placement of the exemplary depressions 18(1a-c) shown in FIG. 1A can be formed through common semiconductor process steps, such as epitaxial overgrowth, dry etching, or wet etching by way of example. In this example, these process steps are done on the first doped active layer 12, which is the first layer being electrically active in the device. Formation of the depressions 18(1a-c) is done prior to the formation of the MQW region 16. The density and size of these selectively formed shaped depressions 18(1a-c) can be advantageously tuned for the purposes of modifying the Indium content to obtain a desired color emission spectrum from the LEDs.

The arrangement of the depressions 18(a-c) can take the form of an array, such as a regular or hexagonal array by way of example, as shown in FIG. 1B. One or more of the same or different shaped depressions 18(1a-c) may be incorporated into a single LED. The depressions 18(1a-c) can take shape as circles, triangles, squares, pentagons, hexagons, or arrangements made of multiple such shapes. Surface treatments can be performed to clean and remove possible surface damage after the creation of the depressions 18(1a-c). In this example, these surface treatments may take the form of a combination of dry and wet etches or cleans, although other treatments and/or processes to remove or minimize surface damage may be used.

Referring to FIG. 1C, in this example the MQW region 16 is formed on the first doped active layer 12 and includes parallel layers of GaN, alloyed with a percentage of Indium to enable a range of light emission between 400 and 600 nm. A representative percentage of Indium can be 18% by way of example. Regions of the parallel layers of the MQW region 16 that conform to the underlying depressions 18(1a-c) have a lower concentration of the alloyed percentage of the Indium than regions of the parallel layers of the MQW region 16 not conforming to the depressions 18(1a-c). These other regions of the parallel layers of the MQW region 16 not conforming to the depressions 18(1a-c) are also referred herein as the planar MQWs. Additionally, in this example the transition regions 22 in FIG. 1C, between the portion of the parallel layers conforming to the depressions 18(1a-c) and the other regions of the parallel layers located outside of those conforming to the depressions 18(1a-c) have a higher concentration of the alloyed percentage of the Indium which decreases in the other regions of the parallel MQW layers with increasing distance from the depressions 18(1a-c).

In this example, the sides of the depressions 18(1a-c) may be surfaces of semi-polar or non-polar crystal planes which contain less Indium due to differences in the Indium sticking coefficient during growth. The semi-polar or non-polar MQWs of the portion of the parallel layers of the MQW region 16 that are in the depressions 18(1a-c) are also thinner than the planar MQWs or other portion of the parallel layers of the MQW region 16. The decrease of Indium in the portion of the parallel layers of the MQW region 16 conforming to the depressions 18(1a-c), relative to the designed planar MQWs 16, is accompanied by an Indium rich “region of transition” or transition region 22 formed in MQWs of the MQW region 16 adjacent to the depressions 18(1a-c). Indium concentration is highest at the periphery of a depression 18(1a-c) and declines with distance from the depression 18(1a-c) to the level of Indium alloying originally incorporated in the designed planar MQWs.

In this example, whereas the Indium poor semi-polar or non-polar MQWs of the MQW region 16 inside the depression 18(1a-c) may have 5-15% Indium, the planar MQWs of the MQW region 16 in each of the transition regions 22 nearest the depression 18(1a-c) have Indium concentrations as high as 30-50%, declining in concentration to the designed 18% Indium in the other portion of the parallel layers of the MQW region 18 with increasing distance from the depression 18(1a-c). This localized increase of Indium is not detrimental to electron-hole recombination efficiency, as is the case with intentionally high Indium content growth for continuous planar MQWs, as these localized increased regions are strain relaxed due to the depression 18(1a-c).

The second active doped layer of opposite charge type is formed on the MQW region 16, in this example the second active doped layer is a p-type AlGaN EBL layer 20 with a layer of p-type GaN 14, although other types and/or numbers of layers may be used and the EBL layer is optional in some examples. The EBL layer 20 is a p-type AlGaN layer and is located over the portion of the parallel layers conforming to all shaped depression 18(1a-c) and on the other regions of the parallel layers outside of the shaped depressions 18(1a-c). By way of example, the p-type EBL 20 (FIG. 1C), referred to in more detail below, could be a 5% Aluminum containing p-AlGaN layer, although other types and/or numbers of electron blocking layers can be used. The p-GaN layer 14 is formed subsequently on the p-type EBL 20, although other types and/or numbers of layers may be formed. When the higher temperature p-GaN 14 is grown on top, the higher surface mobility leads to the depressions 18(1a-c) filling in as shown in the example in FIG. 1C.

In the final structure for this example, the shaped depressions 18(1a-c) are located adjacent to and between these two opposite charge regions, first and second active layers 12 and 14, and where recombination of these charges happens in the InGaN layers of the MQW region 16 to produce light. The depressions 18(1a-c) facilitate a way to easily inject charges into the InGaN layers of the MQW region 16, particularly at low currents. Combined with the mechanism that the depressions 18(1a-c) modify the Indium content in each Indium Gallium Nitride (InGaN) layer in the MQW region 16 in or around each depression 18(1a-c). The charges preferentially recombine initially in the Indium rich areas, leading to longer wavelength emission.

Once the layer structure of a color-tunable LED system 10(1) as shown for example in FIG. 1C is grown, LEDs or other optoelectronic devices can, for example, be conventionally fabricated. For LED formation, patterning specific areas can be done with photolithography for example, where photoresist acts as a mask. Dry etching can then for example be used to selective remove the p-type layer 14, the EBL 20, and MQW region 16, where there is no photoresist, to then access the first active layer of n-type GaN 12. The etching process forms the individual LED structures. Additionally, a top metal or other conductor (not shown) can be deposited on the p-type GaN layer 14, forming the anode. Followed by another metal layer or other conductor (not shown) deposited on the n-type GaN layer 12 which be utilized as the cathode.

Color-tunable LEDs and LED Systems, optionally a common, single crystalline material system also referred to as monolithic, made in accordance with examples of this technology produce a range of desired color emissions from ˜640 nm down to ˜425 nm, spanning the visible spectrum. The color-tunable LED system 10(1) as represented in FIG. 1C illustrates one example of this technology. In this example, low current density applied to the color-tunable LED system 10(1) produces red emission. Emission is significantly blue-shifted with increasing current density. Accordingly, this causes the colors to change from red to orange, to yellow, to green, and then to blue. For smaller LEDs the color emission change requires lower current compared to larger LEDs, as smaller LEDs will have a greater current density at the same applied current as larger LEDs. By way of example, for a 35 μm color-tunable LED the current density ranges from ˜6×10⁻⁵ to ˜8*10⁻² mA/μm² for red and blue respectively.

The emission range of color-tunable LEDs and LED systems as described in the examples herein can be tuned to emit longer or shorter wavelengths as a function of the planar Indium percentage utilized. Increased Indium percentage, such as from 18% to 25% in the planar MQWs of the MQW region 16 increases the inclusion of Indium in the semi-polar or non-polar MQWs of the portion of the MQW region 16 in the depressions 18(1a-c), as well as the localized Indium composition in the planar MQW near to the depressions 18(1a-c). This shifts the total range of optical wavelengths able to be generated from one of the color-tunable LED systems 10(1) to longer wavelengths at both low and high current densities. In contrast, if the designed planar MQW Indium percentage of the MQW region 16 is decreased, such as from 18% to 15% by way of example, depression 18(1a-c) and the region of transition 22 which have incorporation at the same density would similarly shift the range of wavelengths generated to shorter values at both low and high current densities. Where less Indium is incorporated into the semi-polar or non-polar MQWs of the portion of the MQW region 16 in the depressions 18(1a-c), the corresponding Indium rich regions of transition regions 22 of the MQW region 16 also contain less Indium.

In one method of operating an LED in one of the exemplary color-tunable LED system 10(1) such as illustrated in FIG. 1C, a positive bias is applied to the anode, while the cathode is held at ground. Alternatively, the cathode can be held at a negative bias, with respect to a grounded p-type contact. Application of such bias injects holes from the p-type GaN region 14 into the MQWs in the MQW region 16 to recombine with electrons and produce light. However, before this occurs the holes must first overcome an energy barrier in some examples provided by the optional EBL (electron blocking layer) 20. Use of the EBL 20 between the p-type GaN layer 14 and the MQW region 16 creates a large barrier for electrons while creating a smaller barrier for holes. The semi-polar or non-polar planes of the depressions 18(1a-c) in one of the exemplary engineered color-tunable LED system 10(1) have reduced internal piezoelectric fields which lessens the barrier to holes provided by the EBL 20. Thereby, holes (h+) are more easily able to be injected laterally into the Indium rich MQWs rather than vertically to produce a longer wavelength such as emitting the color red. As the current density further increases the holes are able to be injected vertically, populating the planar MQWs located away from each depression 18(1a-c) producing a shorter wavelength color such as green. Increasing the current density further leads to continued band bending, combined with hole population of the thin MQWs in each depression 18(1a-c) producing an even shorter wavelength of light, such a blue. Through these mechanisms, current driven color-tunable emission is achieved.

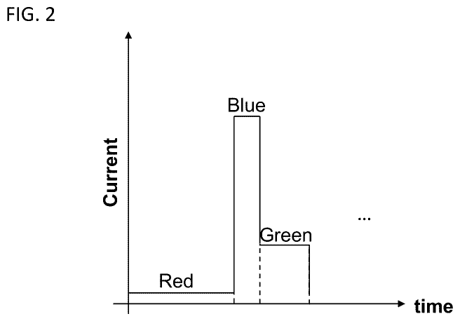

Leveraging the current controlled color tunability of the color-tunable LEDs, pulsed current driving schemes can be advantageously used. Control over the duty-cycle and current level of the applied current can provide brightness control for each monolithic color-tunable LED. To yield equal color brightness, red will have the highest duty cycle of the colors with a low current. Blue, which operates at high current, will have the lowest duty cycle of the colors. In-between colors will operate at current and duty-cycles bounded by red and blue. The driving differences of red, blue, and green for equal brightness are shown graphically in FIG. 2, though not to scale. Tuning the duty-cycle and current for each wavelength makes the viewed intensity appear as the same for each color, as the eye or detectors integrate over the period. The applied current during a period can take many forms including, but not limited to, a square wave, sine wave, or ramp.

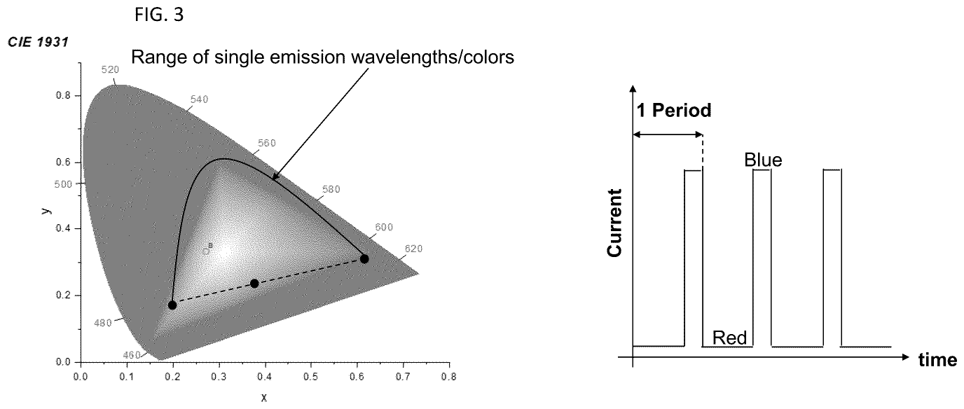

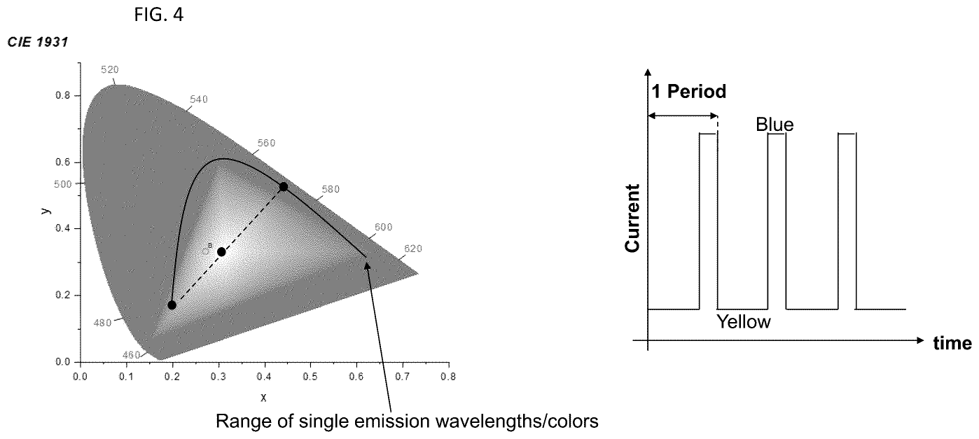

Making use of a tuned duty-cycle and current density for each desired emission wavelength/color, observed full color emission from the color-tunable LEDs in LED system and LED display system pixels can be realized. Conventionally, three LEDs are required to form a pixel, where each LED emits either red, green, or blue. Uniquely enabled by color-tunable LEDs made in accordance with examples of this technology, the number of individual LEDs used for a pixel can be reduced to as few as one. One or more color-tunable LEDs can be driven such that, in each period of the duty-cycle, multiple pulsed wavelengths are emitted such that a single observed color is perceived by the eye. Examples of such an approach can include the emission of red and blue during a single period to emit purple or pink due to the properties of color mixing, FIG. 3. The current duration of red and blue controls the weight of each wavelength to determine the color of emission during the period. A larger blue current duration than what is used to balance the intensity with red will emit purple. A larger red current duration than what is used to balance the intensity with blue will emit pink. Similar principles can be used between green and red wavelengths to emit shades of yellow/orange, or blue and green wavelengths for shades of cyan. Mixing of blue and yellow wavelengths can be leveraged as in conventional lighting to yield emitted white light as seen by the observer, as illustrated in FIG. 4. Wavelength mixing to produce different colors for a single period is possible using the color-tunable LEDs, allowing a single LED to act as a pixel. Instead of fixed operating points of red, green, and blue, the color tunability of a color-tunable LED can, using rapidly changing current in a single period, to produce any color. This enables one LED to function as a single, full color capable, pixel element.

Having the color-tunable LED function as a single pixel element can be realized in a variety of display architectures. By way of example, a passive matrix in which the pixel elements are arrayed together to constitute a display system can be formed. Furthermore, additional device elements can be included with the color-tunable LED to form the basis of a pixel element. An example of this is a transistor integrated with a color-tunable LED to form the basis of a pixel element, though many other device elements such as additional transistors, resistors, and capacitors may also be integrated. These pixel elements which include device elements may similarly be arrayed to form an LED display system, such as device elements comprising transistors which are electrically connected to the LED to control its operational states, including on-off, brightness, etc. If transistors or other device elements connected to the LED in an LED display system use the same material system as the LED, the display system in these examples comprises a common, single crystalline material or monolithic color tunable LED display system.

Pixel elements which are arrayed to form display systems may additionally be integrated with additional circuitry, such as driving circuitry to supply voltage and current to the array by way of example. This additional driving circuitry can take the form of external chips and circuits or may take the form of circuitry, which is monolithically integrated into a common, single crystalline material with the color-tunable LEDs.

Accordingly, as illustrated and described by way of the examples herein, examples of this technology provide color-tunable, optionally common, single crystalline material or monolithic LED systems and LED display systems, which may be effectively utilized in a number of different applications, such as displays, commercial lighting, communications, and more. In particular, examples of this technology provide the integration of color-tunable LEDs without requiring color converters. This capability reduces LED system complexity and offers better performance for increased brightness and efficiency. Examples of this technology are able to provide color-tunable LEDs without Eu doping, use of a porous GaN substrate, or nanowire growth.

Having thus described the basic concept of the technology, it will be rather apparent to those skilled in the art that the foregoing detailed disclosure is intended to be presented by way of example only and is not limiting. Various alterations, improvements, and modifications will occur and are intended to those skilled in the art, though not expressly stated herein. These alterations, improvements, and modifications are intended to be suggested hereby, and are within the spirit and scope of the technology. Additionally, the recited order of processing elements or sequences, or the use of numbers, letters, or other designations therefore, is not intended to limit the scope of the present invention.

What is claimed is:

1. An LED system able to emit a variety of peak wavelengths of light in response to variations in driving current density, the system comprising:
one or more pixel elements that each comprise one or more LEDs each comprising:
a first active doped layer on a substrate and selectively patterned along one surface opposite from the substrate with depressions in one or more shapes and with one or more spacing configurations to promote controlled color emissions in MQW layers of an MQW region;
the MQW region formed over the one surface of the first active doped layer, wherein each of the MQW layers is alloyed with a percentage of Indium to promote the controlled color emissions, wherein portions of the MQW layers that conform to the depressions have a lower concentration of the alloyed percentage of Indium than other portions of the MQW layers; and
a second active doped layer formed on the MQW region that is of opposite in charge to the first active doped layer.

2. The LED systems as set forth in claim 1 further comprising:
a transition region between each of the portions of the MQW layers conforming to the depressions and each of the other portions of the MQW layers and which transition region has a higher concentration of the alloyed percentage of Indium than the other portions of the MQW layers and where the alloyed percentage of Indium decreases with distance from the portions of the MQW layers that conform to the depressions.

3. The LED system as set forth in claim 1 further comprising:
an electron blocking layer included in the second active doped layer.

4. The LED system as set forth in claim 1, wherein the depressions have an inner surface which is at angle with reference to the substrate between 0 and 90 degrees.

5. The LED system as set forth in claim 1, wherein the depressions have an inner surface which is at angle with reference to the substrate between 90 and 180 degrees.

6. The LED system as set forth in claim 1, wherein the depressions are spaced from each other at a distance between 150 nm and 10 μm.

7. The LED system as set forth in claim 1 wherein the depressions each have a top surface diameter from about 150 nm to about 10 μm.

8. The LED system as set forth in claim 1 wherein a depth difference between each of the depressions is a less than about 5 μm.

9. The LED system as set forth in claim 1, wherein the one or more shapes of the outer periphery of the depressions comprise one or more circles, triangles, squares, pentagons, or hexagons.

10. The LED system as set forth in claim 1 wherein the LED system is entirely formed in a common single material system.

11. The LED system as set forth in claim 1 further comprising:
one or more driving circuitry elements coupled to the each of the one or more pixel elements.

12. A method for making an LED system able to emit a variety of peak wavelengths of light in response to variations driving current density, the method comprising:
forming one or more pixel elements each comprising one or more LEDs, wherein the forming further comprises:
providing a first active doped layer on a substrate;
selectively patterning the first active doped layer along one surface opposite from the substrate with depressions in one or more shapes and with one or more spacing configurations to promote controlled color emissions in MQW layers of an MQW region;
forming the MQW region over the one surface of the first active doped layer, wherein each of the MQW layers is alloyed with a percentage of Indium to promote the controlled color emissions, wherein portions of the MQW layers that conform to the depressions have a lower concentration of the alloyed percentage of Indium than other portions of the MQW layers; and
forming a second active doped layer on the MQW region that is of opposite in charge to the first active doped layer.

13. The method as set forth in claim 12 further comprising:
providing a transition region between each of the portions of the MQW layers conforming to the depressions and each of the other portions of the MQW layers and which transition region has a higher concentration of the alloyed percentage of Indium than the other portions of the MQW layers and where the alloyed percentage of Indium decreases with distance from the portions of the MQW layers that conform to the depressions.

14. The method as set forth in claim 12 further comprising:
forming an electron blocking layer included in the second active doped layer.

15. The method as set forth in claim 12, wherein the depressions have an inner surface which is at angle with reference to the substrate between 0 and 90 degrees.

16. The method as set forth in claim 12, wherein the depressions have an inner surface which is at angle with reference to the substrate between 90 and 180 degrees.

17. The method as set forth in claim 12, wherein the depressions are spaced from each other at a distance between 150 nm and 10 μm.

18. The method as set forth in claim 12 wherein the depressions each have a top surface diameter from about 150 nm to about 10 μm

19. The method as set forth in claim 12 wherein a depth difference between each of the depressions is a less than about 5 μm.

20. The method as set forth in claim 12, wherein the one or more shapes of the outer periphery of the depressions comprise one or more circles, triangles, squares, pentagons, or hexagons.

21. The method as set forth in claim 12 wherein the LED system is entirely formed in a common single material system.

22. The method as set forth in claim 12 further comprising:
forming one or more driving circuitry elements which are coupled to the each of the one or more pixel elements.

23. A method for controlling one or more colored emissions, the method comprising:
providing an LED system comprising a first active doped layer, an MQW region, and a second active dope layer;
wherein the first active doped layer is selectively patterned along one surface opposite from the substrate with depressions in one or more shapes and with one or more spacing configurations to promote controlled color emissions in MQW layers of an MQW region;
wherein the MQW region is formed over the one surface of the first active doped layer, wherein each of the MQW layers is alloyed with a percentage of Indium to promote the controlled color emissions, wherein portions of the MQW layers that conform to the depressions have a lower concentration of the alloyed percentage of Indium than other portions of the MQW layers; and
wherein the second active doped layer is formed on the MQW region that is of opposite in charge to the first active doped layer; and
varying an application of current over time to the LED system to alter the one or more color emissions.

24. The method as described in claim 23 wherein the varying the application of current over time further comprises:
varying a duty-cycle and current level each wavelength of emission.

25. The method as described in claim 23 wherein the varying the application of current over time has a frequency is greater than 60 Hz.

26. The method as described in claim 25 wherein the varying the application of current over time further comprises:
mixing of two or more wavelengths each with a unique current level and duty-cycle in a single period.
